(19) United States
(12) Patent Application Publication
(10) Pub. No.: US 2025/0149309 A1
(43) Pub. Date: May 8, 2025

(54) PLASMA PROCESSING APPARATUS AND PLASMA PROCESSING METHOD

(71) Applicant: Tokyo Electron Limited, Tokyo (JP)

(72) Inventors: Hiroki SATO, Miyagi (JP); Yuki KAWADA, Miyagi (JP); Akihiro YOKOTA, Miyagi (JP)

(73) Assignee: Tokyo Electron Limited, Tokyo (JP)

(21) Appl. No.: 19/018,319

(22) Filed: Jan. 13, 2025

Related U.S. Application Data
(63) Continuation of application No. PCT/JP2023/025675, filed on Jul. 12, 2023.

(30) Foreign Application Priority Data
Jul. 20, 2022 (JP) 2022-115381

(51) Int. Cl. H01J 37/32; H01F 7/08

(52) U.S. Cl. CPC H01J 37/3266; H01F 7/081; H01J 37/32642; H01F 2007/083; H01J 37/32091

(57) ABSTRACT

A plasma processing apparatus disclosed herein includes a chamber, a substrate support, a plasma generator, at least one electromagnet, and a power source. The substrate support is provided in the chamber. The substrate support includes a first region on which a substrate is placeable and a second region which surrounds the first region and on which an edge ring is placed. The plasma generator is configured to generate a plasma in the chamber. The at least one electromagnet is configured to generate a magnetic field localized in an annular space above the edge ring. The power source is electrically connected to the at least one electromagnet and is configured to adjust a strength of the magnetic field.

### CROSS-REFERENCE TO RELATED APPLICATIONS

This application is a bypass continuation application of international application No. PCT/JP2023/025675 having an international filing date of Jul. 12, 2023 and designating the United States, the international application being based upon and claiming the benefit of priority from Japanese Patent Application No. 2022-115381, filed on Jul. 20, 2022, the entire contents of each are incorporated herein by reference.

### TECHNICAL FIELD

Exemplary embodiments of the present disclosure relate to a plasma processing apparatus and a plasma processing method.

### BACKGROUND

A plasma processing apparatus is used in plasma processing with respect to a substrate. The plasma processing apparatus includes a chamber and a substrate support. The substrate support is provided in the chamber. The substrate support supports the substrate. Further, the substrate support supports an edge ring disposed to surround the substrate. JP2008-16727A below discloses such a plasma processing apparatus.

### CITATION LIST

### Patent Documents

Patent Document 1: JP2008-16727A

### SUMMARY

The present disclosure provides a technique for adjusting a thickness of a plasma sheath above an edge ring.

In an exemplary embodiment, a plasma processing apparatus is provided. The plasma processing apparatus includes a chamber, a substrate support, a plasma generator, at least one electromagnet, and a power source. The substrate support is provided in the chamber. The substrate support includes a first region on which a substrate is placeable and a second region which surrounds the first region and on which an edge ring is placed. The plasma generator is configured to generate plasma in the chamber. The at least one electromagnet is configured to generate a magnetic field localized in an annular space above the edge ring. The power source is electrically connected to the at least one electromagnet and is configured to adjust a strength of the magnetic field.

According to the exemplary embodiment, it is possible to adjust the thickness of the plasma sheath above the edge ring.

### BRIEF DESCRIPTION OF DRAWINGS

FIG. 1 is a view for describing a configuration example of a plasma processing system.

FIG. 2 is a view for describing a configuration example of a capacitively-coupled plasma processing apparatus.

FIG. 3 is a partially enlarged cross-sectional view of a substrate support including an electromagnet unit of the plasma processing apparatus according to an exemplary embodiment.

FIG. 4 is a partially enlarged cross-sectional view of the substrate support including the electromagnet unit of the plasma processing apparatus according to the exemplary embodiment.

FIG. 5 is a plan view of the electromagnet unit of the plasma processing apparatus according to the exemplary embodiment.

FIG. 6 is a partially enlarged cross-sectional view of a substrate support including an electromagnet unit of a plasma processing apparatus according to another exemplary embodiment.

FIG. 7 is a partially enlarged cross-sectional view of a substrate support including an electromagnet unit of a plasma processing apparatus according to still another exemplary embodiment.

FIG. 8 is a plan view of the electromagnet unit of the plasma processing apparatus according to the still another exemplary embodiment.

FIG. 9 is a partially enlarged cross-sectional view of a substrate support including an electromagnet unit of a plasma processing apparatus according to still further another exemplary embodiment.

FIG. 10 is a plan view of the electromagnet unit of the plasma processing apparatus according to the still further another exemplary embodiment.

FIG. 11 is a flowchart of a plasma processing method according to an exemplary embodiment.

### DETAILED DESCRIPTION

Hereinafter, various exemplary embodiments will be described in detail with reference to the drawings. Further, like reference numerals will be given to like or corresponding parts throughout the drawings.

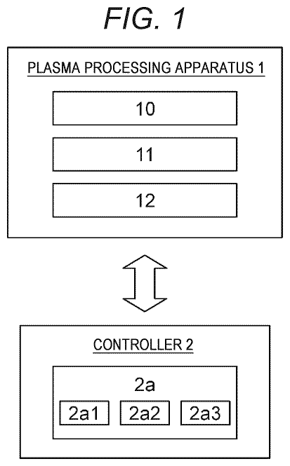

FIG. 1 is a diagram for explaining an example of a configuration of a plasma processing system. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to a gas supply 20 which will be described later, and the gas exhaust port is connected to an exhaust system 40 which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be Capacitively Coupled Plasma (CCP), Inductively Coupled Plasma (ICP), Electron-Cyclotron-Resonance Plasma (ECR plasma), Helicon Wave Plasma (HWP), Surface Wave Plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

The processor 2a1 may be embodied by circuitry. That is, implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein.

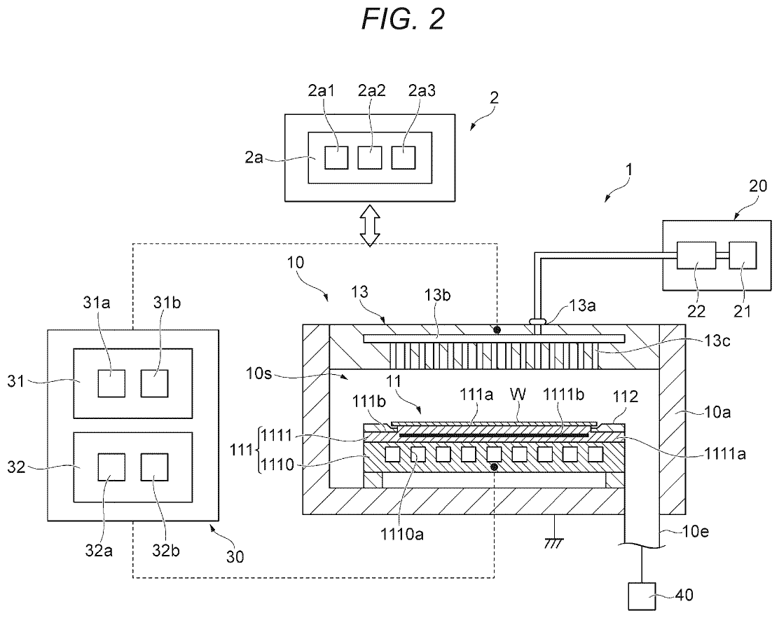

Hereinafter, a configuration example of a capacitively-coupled plasma processing apparatus as an example of the plasma processing apparatus 1 will be described. FIG. 2 is a view for explaining an example of a configuration of a capacitively-coupled plasma processing apparatus.

The capacitively-coupled plasma processing apparatus 1 includes the plasma processing chamber 10, the gas supply 20, a power source 30, and the exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and an edge ring 112. The main body 111 has a central region 111a which supports a substrate W, and an annular region 111b which supports the edge ring 112. A wafer is an example of the substrate W. The annular region 111b of the main body 111 surrounds the central region 111a of the main body 111 in a plan view. The substrate W is disposed on the central region 111a of the main body 111, and the edge ring 112 is disposed on the annular region 111b of the main body 111 so as to surround the substrate W on the central region 111a of the main body 111. Accordingly, the central region 111a is also referred to as a substrate support surface for supporting the substrate W, and the annular region 111b is also referred to as a ring support surface for supporting the edge ring 112. The edge ring 112 is made of a conductive material or an insulating material.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the edge ring 112 may be disposed on the annular electrostatic chuck or the annular insulating member or may be disposed on both the electrostatic chuck 1111 and the annular insulating member. Further, at least one RF/DC electrode coupled to an RF power source 31 and/or a DC power source 32 to be described later may be disposed in the ceramic member 1111a. In this case, at least one RF/DC electrode functions as the lower electrode. In a case where a bias RF signal and/or a DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

Further, the substrate support 11 may include a temperature controlling module configured to adjust a temperature of at least one of the electrostatic chuck 1111, the edge ring 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes the RF power source 31 coupled to plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a part of the plasma generator 12. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include the DC power source 32 coupled to the plasma processing chamber 10. The DC power source 32 includes a first DC generator 32a and a second DC generator 32b. In one embodiment, the first DC generator 32a is configured to be connected to at least one lower electrode to generate a first DC signal. The generated first DC signal is applied to at least one lower electrode. In one embodiment, the second DC generator 32b is configured to be connected to at least one upper electrode to generate a second DC signal. The generated second DC signal is applied to at least one upper electrode.

In various embodiments, the first and second DC signals may be pulsed. In this case, the sequence of voltage pulses is applied to at least one lower electrode and/or at least one upper electrode. The voltage pulse may have a pulse waveform of a rectangle, a trapezoid, a triangle, or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

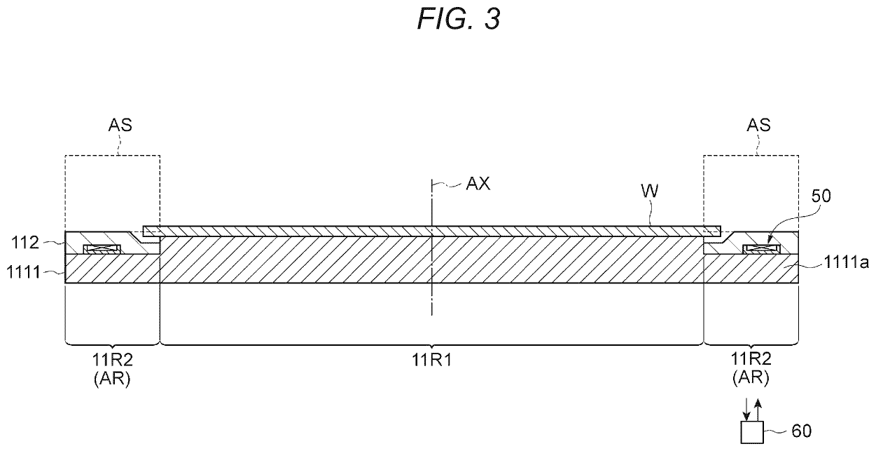

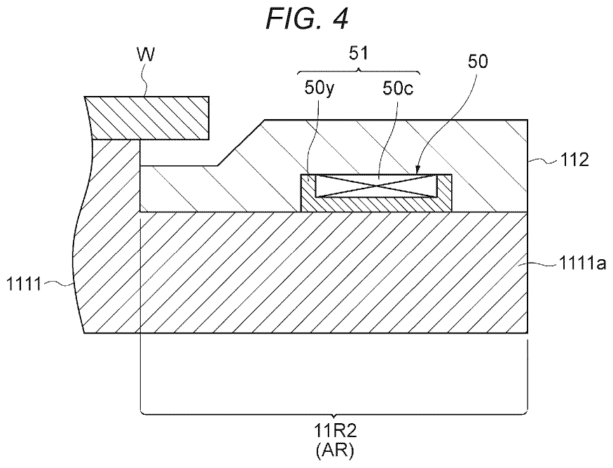

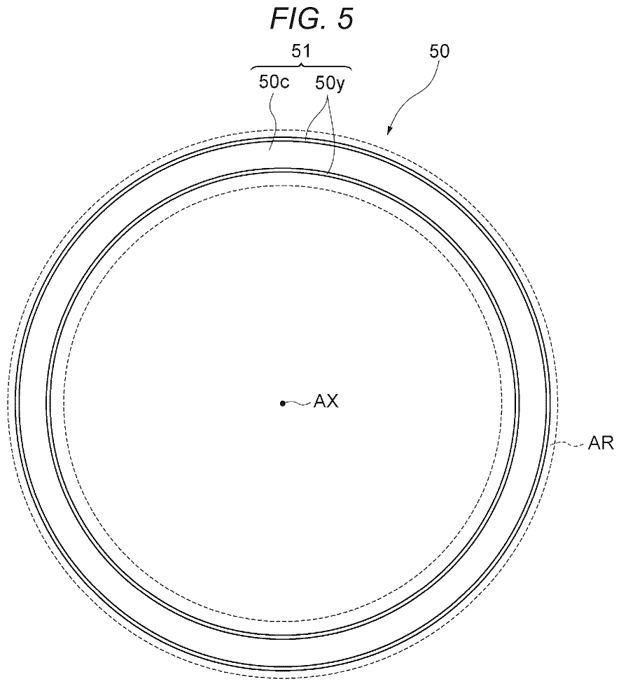

Hereinafter, FIGS. 3 to 5 will be referred to together with FIG. 2. FIGS. 3 and 4 are partially enlarged cross-sectional views of the substrate support including an electromagnet unit of the plasma processing apparatus according to the exemplary embodiment. FIG. 5 is a plan view of the electromagnet unit of the plasma processing apparatus according to the exemplary embodiment.

The substrate support 11 includes a first region 11R1 and a second region 11R2. The first region 11R1 is a region that supports the substrate W placed thereon. An upper surface of the first region 11R1 is the central region 111a described above. The first region 11R1 has a circular shape in a plan view, and a center axis thereof is an axis AX. The substrate W is placed on the first region 11R1 such that a center thereof is positioned on the axis AX.

The second region 11R2 is a region that supports the edge ring 112 placed thereon. The second region 11R2 surrounds the first region 11R1. The second region 11R2 has an annular shape in a plan view. A center axis of the second region 11R2 is the axis AX. The edge ring 112 is placed on the second region 11R2 such that a center axis of the edge ring 112 is positioned on the axis AX.

The plasma processing apparatus 1 further includes an electromagnet unit 50. The electromagnet unit 50 includes at least one electromagnet. The electromagnet unit 50 is configured to generate a magnetic field localized in an annular space AS above the edge ring 112. The annular space AS is a space in the chamber 10.

The plasma processing apparatus 1 further includes a power source 60. The power source 60 is a power source that supplies a current to a coil, which is to be described later, of the electromagnet unit 50. The power source 60 is configured to adjust a strength of the magnetic field generated by the electromagnet unit 50 by adjusting the current supplied to the coil.

The at least one electromagnet of the electromagnet unit 50 may be provided in an annular placement region AR. The annular placement region AR is located in the second region 11R2 or in the edge ring 112 and extends around the axis AX. The at least one electromagnet of the electromagnet unit 50 may be provided in the second region 11R2 and in the ceramic member 1111a of the electrostatic chuck 1111. Alternatively, the at least one electromagnet of the electromagnet unit 50 may be covered with the edge ring 112 on the second region 11R2.

In the embodiments shown in FIGS. 3 to 5, the electromagnet unit 50 includes a single electromagnet 51. The electromagnet 51 is an annular electromagnet and includes a coil 50c and a yoke 50y. The coil 50c is provided in the annular placement region AR and is wound around the axis AX. The yoke 50y exposes an upper end of the coil 50c, and surrounds an inner edge, an outer edge, and a bottom of the coil 50c. The yoke 50y is made of a magnetic material such as an iron material. The yoke 50y includes two tubular portions and a bottom. The bottom of the yoke 50y has an annular shape in a plan view and extends around the axis AX. The two tubular portions of the yoke 50y extend coaxially around the axis AX and extend upward from the bottom of the yoke 50y. The coil 50c is provided on the bottom of the yoke 50y and between the two tubular portions of the yoke 50y.

In the plasma processing apparatus 1, the strength of the magnetic field in the annular space AS above the edge ring 112 can be adjusted. When the strength of the magnetic field in the annular space AS is high, an electron density in the annular space AS becomes high, and a thickness of a sheath (plasma sheath) becomes small. On the other hand, when the strength of the magnetic field in the annular space AS is low, the electron density in the annular space AS becomes low, and the thickness of the sheath becomes large. Therefore, according to the plasma processing apparatus 1, it is possible to adjust the thickness of the plasma sheath above the edge ring 112. Therefore, according to the plasma processing apparatus 1, it is possible to adjust an incidence angle of ions from the plasma with respect to an edge of the substrate W.

In one embodiment, the controller 2 may control the power source 60 to reduce the current supplied to the coil 50c so as to reduce the strength of the magnetic field as a thickness of the edge ring 112 reduces. The controller 2 may specify the thickness of the edge ring 112 based on a measurement value that reflects a time at which the edge ring 112 is exposed to the plasma or the thickness of the edge ring 112. The measurement value that reflects the thickness of the edge ring 112 may be obtained by an electric or optical sensor. The controller 2 may use a data table or function prepared in advance to determine the current supplied to the coil 50c according to the thickness of the edge ring 112. In this case, the smaller the thickness of the edge ring 112, the larger the thickness of the plasma sheath above the edge ring 112. Therefore, it becomes possible to correct the incidence angle of ions from the plasma with respect to the edge of the substrate W to a vertical angle according to the thickness of the edge ring 112.

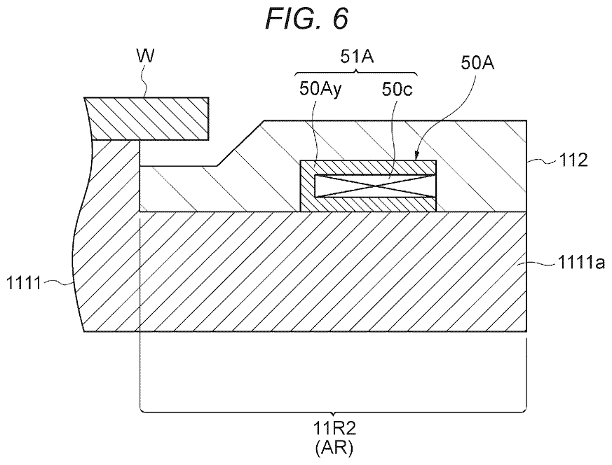

Hereinafter, FIG. 6 will be referred to. FIG. 6 is a partially enlarged cross-sectional view of a substrate support including an electromagnet unit of a plasma processing apparatus according to another exemplary embodiment. An electromagnet unit 50A shown in FIG. 6 may be adopted in the plasma processing apparatus 1 instead of the electromagnet unit 50. Similar to the electromagnet unit 50, the electromagnet unit 50A is also configured to generate a magnetic field localized in the annular space AS.

Similar to the electromagnet unit 50, the electromagnet unit 50A includes a single electromagnet 51A. The electromagnet 51A includes a yoke 50Ay having a shape different from that of the yoke 50y. Other configurations of the electromagnet unit 50A are the same as the corresponding configurations of the electromagnet unit 50.

As shown in FIG. 6, the yoke 50Ay exposes the outer edge of the coil 50c, and surrounds the inner edge, the upper end, and the bottom of the coil 50c. The yoke 50Ay includes a bottom, a tubular portion, and an upper portion. Each of the bottom and the upper portion of the yoke 50Ay has a substantially annular shape in a plan view, and extends around the axis AX. The upper portion of the yoke 50Ay extends above the bottom of the yoke 50Ay. The tubular portion of the yoke 50Ay extends around the axis AX and extends between an inner edge of the bottom and an inner edge of the upper portion of the yoke 50Ay. The coil 50c is disposed in a region surrounded by the bottom, the tubular portion, and the upper portion of the yoke 50Ay.

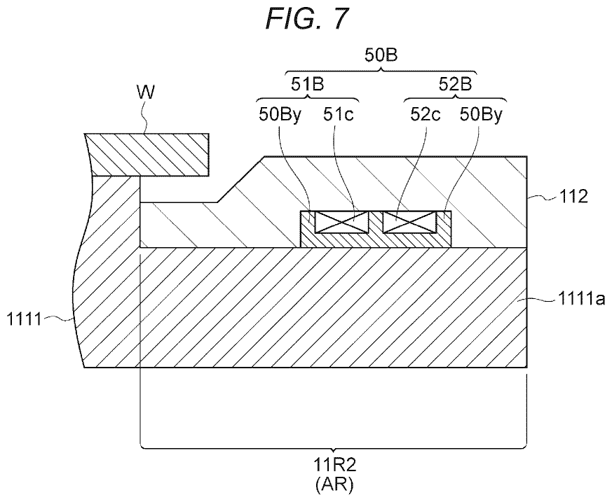

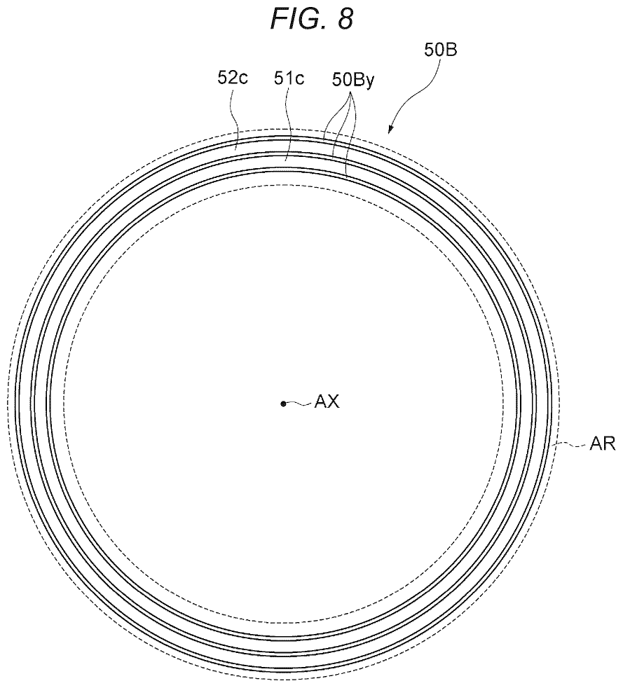

Hereinafter, reference will be made to FIGS. 7 and 8. FIG. 7 is a partially enlarged cross-sectional view of a substrate support including an electromagnet unit of a plasma processing apparatus according to still another exemplary embodiment. FIG. 8 is a plan view of the electromagnet unit of the plasma processing apparatus according to the still another exemplary embodiment. An electromagnet unit 50B shown in FIGS. 7 and 8 may be adopted in the plasma processing apparatus 1 instead of the electromagnet unit 50. Similar to the electromagnet unit 50, the electromagnet unit 50B is also configured to generate a magnetic field localized in the annular space AS.

The electromagnet unit 50B includes a first electromagnet 51B and a second electromagnet 52B. The first electromagnet 51B and the second electromagnet 52B are provided in the annular placement region AR. Each of the first electromagnet 51B and the second electromagnet 52B is an annular electromagnet and extends around the axis AX. The second electromagnet 52B is provided outside the first electromagnet 51B (outer side in a radial direction with respect to the axis AX).

The first electromagnet 51B includes a coil 51c. The second electromagnet 52B includes a coil 52c. Each of the coils 51c and 52c is wound around the axis AX. The coil 52c is disposed outside the coil 51c to surround the coil 51c.

In one embodiment, the electromagnet unit 50B may further include a yoke 50By. The yoke 50By is made of a magnetic material such as an iron material. The yoke 50By is provided to expose upper ends of the respective coils 51c and 52c, and to surround inner edges, outer edges, and bottoms of the respective coils 51c and 52c.

The yoke 50By may include three tubular portions and a bottom. The bottom of the yoke 50By has a substantially annular shape in a plan view and extends around the axis AX. The three tubular portions of the yoke 50By extend coaxially around the axis AX and extend upward from the bottom of the yoke 50By. The coil 51c is provided on the bottom of the yoke 50By and between two inner tubular portions among the three tubular portions of the yoke 50By. The coil 52c is provided on the bottom of the yoke 50By and between two outer tubular portions among the three tubular portions of the yoke 50By. According to the yoke 50By, it is possible to further increase a degree of localization of the magnetic field generated in the annular space AS by the electromagnet unit 50B.

In the plasma processing apparatus 1 including the electromagnet unit 50B, the power source 60 is configured to adjust a strength of the magnetic field generated by the electromagnet unit 50B by adjusting currents supplied to the coils 51c and 52c respectively. A direction of the current flowing through the coil 51c and a direction of the current flowing through the coil 52c may be the same direction or may be opposite directions. When the direction of the current flowing through the coil 51c and the direction of the current flowing through the coil 52c are opposite directions, the degree of localization of the magnetic field formed in the annular space AS by the electromagnet unit 50B can be further increased.

In one embodiment, the controller 2 may control the power source 60 to reduce the currents supplied to the coils 51c and 52c so as to reduce the strength of the magnetic field as the thickness of the edge ring 112 decreases. The controller 2 may use a data table or function prepared in advance to determine the currents supplied to the coils 51c and 52c according to the thickness of the edge ring 112. In this case, it becomes possible to correct an incidence angle of ions from a plasma with respect to the edge of the substrate W to a vertical angle according to the thickness of the edge ring 112.

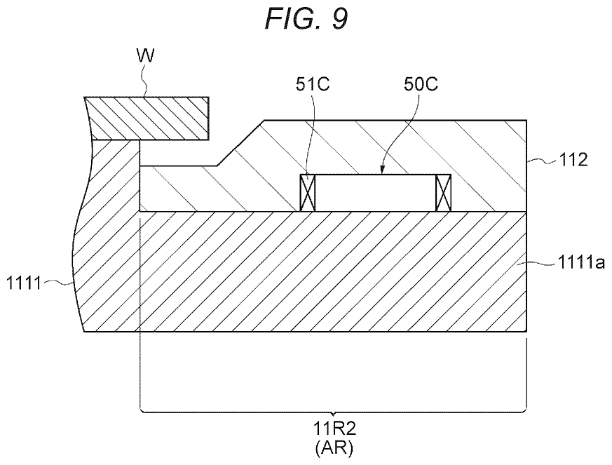

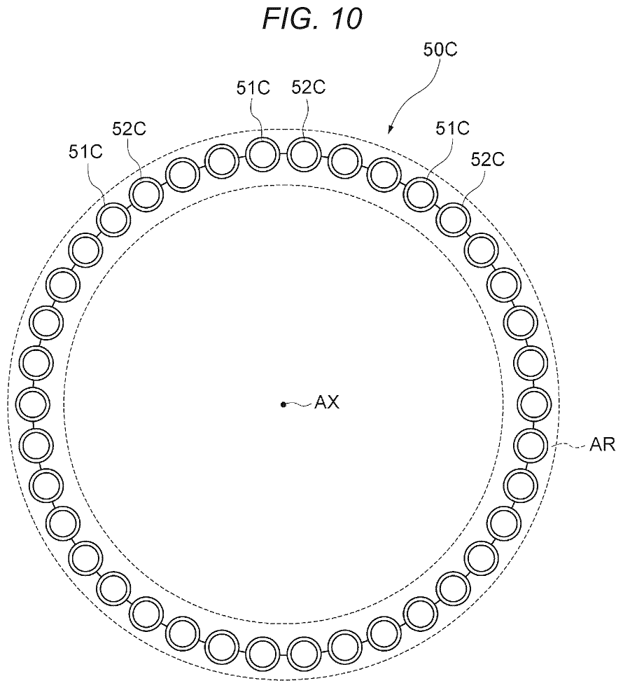

Hereinafter, reference will be made to FIGS. 9 and 10. FIG. 9 is a partially enlarged cross-sectional view of a substrate support including an electromagnet unit of a plasma processing apparatus according to still another exemplary embodiment. FIG. 10 is a plan view of the electromagnet unit of the plasma processing apparatus according to the still further another exemplary embodiment. An electromagnet unit 50C shown in FIGS. 9 and 10 may be adopted in the plasma processing apparatus 1 instead of the electromagnet unit 50. Similar to the electromagnet unit 50, the electromagnet unit 50C is also configured to generate a magnetic field localized in the annular space AS.

The electromagnet unit 50C includes a plurality of electromagnets 51C and a plurality of electromagnets 52C. Each of the plurality of electromagnets 51C and the plurality of electromagnets 52C includes a coil. The coil of each of the plurality of electromagnets 51C and the plurality of electromagnets 52C is wound around an axis extending along a direction in which the axis AX extends. The plurality of electromagnets 51C and the plurality of electromagnets 52C are provided in the annular placement region AR. The plurality of electromagnets 51C and the plurality of electromagnets 52C are alternately arranged along a circumferential direction around the axis AX.

In the plasma processing apparatus 1 provided with the electromagnet unit 50C, the power source 60 is configured to adjust a strength of the magnetic field generated by the electromagnet unit 50C by adjusting currents supplied to the coils of the plurality of electromagnets 51C and the plurality of electromagnets 52C, respectively.

Further, the plurality of electromagnets 51C and the plurality of electromagnets 52C are configured such that north poles and south poles alternately appear along the circumferential direction in the annular placement region AR. When the coils of the plurality of electromagnets 51C and the coils of the plurality of electromagnets 52C are wound in the same direction, directions of the currents flowing through the coils of the respective electromagnets 51C and directions of the currents flowing through the coils of the respective electromagnets 52C may be opposite directions. Alternatively, the coils of the plurality of electromagnets 51C and the coils of the plurality of electromagnets 52C may be wound in opposite directions.

In one embodiment, the controller 2 may control the power source 60 to reduce the currents supplied to the coils of the plurality of electromagnets 51C and the plurality of electromagnets 52C so as to reduce the strength of the magnetic field as the thickness of the edge ring 112 decreases. The controller 2 may use a data table or function prepared in advance to determine the currents supplied to the coils of the plurality of electromagnets 51C and the plurality of electromagnets 52C according to the thickness of the edge ring 112. In this case, it becomes possible to correct an incidence angle of ions from a plasma with respect to the edge of the substrate W to a vertical angle according to the thickness of the edge ring 112.

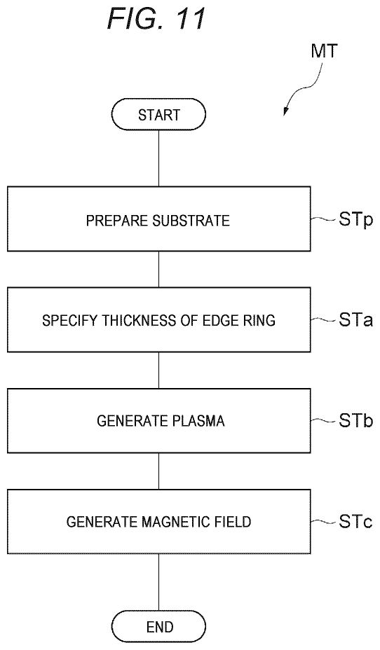

Hereinafter, FIG. 11 will be referred to. FIG. 11 is a flowchart of a plasma processing method according to an exemplary embodiment. The plasma processing method shown in FIG. 11 (hereinafter referred to as a “method MT”) may be performed using the plasma processing apparatus 1. In each step of the method MT, each unit of the plasma processing apparatus 1 may be controlled by the controller 2.

The method MT starts from step STp. In step STp, the substrate W is placed on the substrate support 11 in the chamber 10. In step STa, the thickness of the edge ring 112 is specified. For the specification of the thickness of the edge ring 112, please refer to the description given above related to the plasma processing apparatus 1.

In step STb, the plasma is generated from a gas in the chamber 10. In step STb, the gas is supplied from the gas supply 20 into the chamber 10. Further, a pressure in the chamber 10 is adjusted to a designated pressure by the exhaust system 40. Further, the plasma is generated from the gas in the chamber 10 by the plasma generator 12.

Step STc is performed when the plasma is generated in step STb. In step STc, a magnetic field having a strength adjusted according to the thickness of the edge ring 112 is generated by the electromagnet unit (electromagnet units 50, 50A, 50B, or 50C) of the plasma processing apparatus 1. As described above, the magnetic field is localized in the annular space AS. As described above, the strength of the magnetic field is adjusted so as to decrease as the thickness of the edge ring 112 decreases.

Although various exemplary embodiments have been described above, various additions, omissions, substitutions and changes may be made without being limited to the exemplary embodiments described above. In addition, other embodiments may be formed by combining elements in different embodiments.

Hereinafter, first to fifteenth simulations performed for evaluating the plasma processing apparatus 1 will be described.

In the first simulation, the magnetic field generated by the electromagnet unit 50 was calculated. In the second simulation, the magnetic field when the yoke 50y is removed from the electromagnet 51 of the electromagnet unit 50 was calculated. In the third simulation, the magnetic field generated by the electromagnet unit 50A was calculated. In the first to third simulations, the current supplied to the coil 50c was 1 (A).

In the fourth to fifteenth simulations, the magnetic field generated by the electromagnet unit 50B was calculated. In the fourth to fifteenth simulations, a total of the current supplied to the coil 51c and the current supplied to the coil 52c was set to 2 (A). In the fourth to ninth simulations, the direction of the current to supplied the coil 51c and the direction of the current supplied to the coil 52c were the same direction. In the tenth to fifteenth simulations, the direction of the current supplied to the coil 51c and the direction of the current supplied to the coil 52c were opposite directions. In the fourth to sixth simulations and the tenth to twelfth simulations, the yoke 50By was removed from the electromagnet unit 50B. In the seventh to ninth simulations and the thirteenth to fifteenth simulations, the electromagnet unit 50B had the yoke 50By. In the fourth to sixth simulations, a ratio of the current supplied to the coil 51c to the current supplied to the coil 52c was set to 25:75, 50:50, and 75:25. In the seventh to ninth simulations, the ratio of the current supplied to the coil 51c to the current supplied to the coil 52c was set to 25:75, 50:50, and 75:25. In the tenth to twelfth simulations, the ratio of the current supplied to the coil 51c to the current supplied to the coil 52c was set to 25:75, 50:50, and 75:25. In the thirteenth to fifteenth simulations, the ratio of the current supplied to the coil 51c to the current supplied to the coil 52c was set to 25:75, 50:50, and 75:25.

In the first to fourteenth simulations, B_{ER}/B_{W} was calculated as an index of the localization of the magnetic field. B_{W} represents a strength (magnetic flux density) of the magnetic field on the substrate W, at a distance of 150 mm from the axis AX. B_{ER} is a maximum value of the strength (magnetic flux density) of the magnetic field above the edge ring 112.

A value of B_{ER}/B_{W} in the first simulation was 3.1, and the value of B_{ER}/B_{W} in the second simulation was 2.0. Therefore, it has been confirmed that the degree of localization of the magnetic field of the electromagnet unit 50 can be increased by the yoke 50y. Further, the value of B_{ER}/B_{W} in the third simulation was 2.9. Therefore, it has been confirmed that the degree of localization of the magnetic field of the electromagnet unit 50A can also be increased by the yoke 50Ay.

The values of B_{ER}/B_{W} in the fourth to sixth simulations were 2.0, 2.4, and 2.2, respectively. In addition, the values of B_{ER}/B_{W} in the seventh to ninth simulations were 3.3, 3.0, and 3.0, respectively. Therefore, it has been confirmed that in a case where the electromagnet unit 50B is used, the magnetic field can be localized even when the direction of the current supplied to the coil 51c and the direction of the current supplied to the coil 52c are the same, and even when the yoke 50By is removed. Further, it has been confirmed that by using the yoke 50By, it is possible to further increase the degree of localization of the magnetic field.

The values of B_{ER}/B_{W} in the tenth to twelfth simulations were 3.1, 5.8, and 2.1, respectively. The values of B_{ER}/B_{W} in the thirteenth to fifteenth simulations were 4.9, 9.2, and 3.2, respectively. As a result of the fourth to fifteenth simulations, it has been confirmed that the degree of localization of the magnetic field can be further increased when the direction of the current supplied to the coil 51c and the direction of the current supplied to the coil 52c are opposite directions.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A plasma processing apparatus comprising:
a chamber;
a substrate support provided in the chamber and including a first region on which a substrate is placeable and a second region which surrounds the first region and on which an edge ring is placed;
a plasma generator configured to generate a plasma in the chamber;
at least one electromagnet configured to generate a magnetic field localized in an annular space above the edge ring; and
a power source electrically connected to the at least one electromagnet and configured to adjust a strength of the magnetic field.

2. The plasma processing apparatus according to claim 1, wherein the at least one electromagnet is provided in an annular placement region extending around a center axis of the second region in the second region or the edge ring.

3. The plasma processing apparatus according to claim 2, wherein
the at least one electromagnet is a single electromagnet, and
the single electromagnet includes
a coil wound around the center axis in the annular placement region, and
a yoke exposing an upper end of the coil and surrounding an inner edge, an outer edge, and a bottom of the coil.

4. The plasma processing apparatus according to claim 2, wherein
the at least one electromagnet is a single electromagnet, and
the single electromagnet includes
a coil wound around the center axis in the annular placement region, and
a yoke exposing an outer edge of the coil and surrounding an inner edge, an upper end, and a bottom of the coil.

5. The plasma processing apparatus according to claim 2, wherein
the at least one electromagnet includes a first electromagnet and a second electromagnet,
each of the first electromagnet and the second electromagnet includes a coil wound around the center axis in the annular placement region, and
the coil of the second electromagnet is disposed to surround the coil of the first electromagnet.

6. The plasma processing apparatus according to claim 5, wherein the at least one electromagnet further includes a yoke exposing an upper end of the coil of each of the first electromagnet and the second electromagnet and surrounding an inner edge, an outer edge, and a bottom of the coil of each of the first electromagnet and the second electromagnet.

7. The plasma processing apparatus according to claim 2, wherein
the at least one electromagnet includes a plurality of electromagnets,
each of the plurality of electromagnets includes a coil wound around an axis thereof extending along a direction in which the center axis extends, and
the plurality of electromagnets are arranged along a circumferential direction with respect to the center axis in the annular placement region and are configured such that a north pole and a south pole alternately appear.

8. The plasma processing apparatus according to claim 1, further comprising:
circuitry configured to control the power source to decrease the strength of the magnetic field as a thickness of the edge ring decreases.

9. The plasma processing apparatus according to claim 2, further comprising:
circuitry configured to control the power source to decrease the strength of the magnetic field as a thickness of the edge ring decreases.

10. The plasma processing apparatus according to claim 3, further comprising:
circuitry configured to control the power source to decrease the strength of the magnetic field as a thickness of the edge ring decreases.

11. The plasma processing apparatus according to claim 4, further comprising:
circuitry configured to control the power source to decrease the strength of the magnetic field as a thickness of the edge ring decreases.

12. The plasma processing apparatus according to claim 5, further comprising:
circuitry configured to control the power source to decrease the strength of the magnetic field as a thickness of the edge ring decreases.

13. The plasma processing apparatus according to claim 6, further comprising:
circuitry configured to control the power source to decrease the strength of the magnetic field as a thickness of the edge ring decreases.

14. The plasma processing apparatus according to claim 7, further comprising:
circuitry configured to control the power source to decrease the strength of the magnetic field as a thickness of the edge ring decreases.

15. A plasma processing method comprising:
generating a plasma in a chamber of a plasma processing apparatus, the plasma processing apparatus including the chamber, a substrate support provided in the chamber and including a first region on which a substrate is placed and a second region which surrounds the first region and on which an edge ring is placed, a plasma generator configured to generate a plasma in the chamber, at least one electromagnet configured to generate a magnetic field localized in an annular space above the edge ring, and a power source electrically connected to the at least one electromagnet and configured to adjust a strength of the magnetic field; and
generating, when the plasma is being generated, the magnetic field having the strength adjusted according to a thickness of the edge ring.

16. The plasma processing method according to claim 15, wherein the strength of the magnetic field is adjusted to decrease as the thickness of the edge ring decreases.
